(19) United States
(12) Patent Application Publication
(10) Pub. No.: US 2023/0351954 A1
(43) Pub. Date: Nov. 2, 2023

(54) DISPLAY DRIVER CHIP FOR DRIVING A PLURALITY OF PIXELS OF A DISPLAY PANEL

(71) Applicant: NOVATEK MICROELECTRONICS CORP., HSINCHU (TW)

(72) Inventor: JHIH-SIOU CHENG, NEW TAIPEI CITY (TW)

(21) Appl. No.: 18/318,965

(22) Filed: May 17, 2023

Related U.S. Application Data
(63) Continuation-in-part of application No. 17/661,195, filed on Apr. 28, 2022.

(51) Int. Cl. G09G 3/3225; G09G 3/20; H01L 23/00

(52) U.S. Cl. CPC G09G 3/3225; G09G 3/2096; H01L 24/06; G09G 2300/0842; G09G 2330/021; G09G 2320/0626; H01L 2224/06155; H01L 23/49838

(57) ABSTRACT

A display driver chip for driving a plurality of pixels of a display panel is provided. The proposed display driver chip is attached on a chip on film package and includes a plurality of input power pads, output power pads, output data pads and a power multiplexer. The output power pads and output data pads are located on the same side of the display driver chip. And the power multiplexer is adapted to receive a plurality of power voltages such that the power multiplexer selects one power voltage out of the plurality of power voltages for outputting to one of the output power pads. By employing the proposed display driver chip, a high or low power voltage can be selected to drive the display panel according to the brightness to be shown. As such, the present invention is effective in reducing IC power consumption and suppressing redundant power waste.

### CROSS-REFERENCE TO RELATED APPLICATION

This application is a Continuation in Part of co-pending application Ser. No. 17/661,195, filed on 28 Apr. 2022, for which priority is claimed under 35 U.S.C. § 120 and the entire contents of all of which are hereby incorporated by reference.

### BACKGROUND OF THE INVENTION

### Field of the Invention

The present invention is related to a display driver chip. And more particularly, the present invention is directed to provide a display driver chip which is attached on a chip on film package and is applicable to driving a plurality of pixels of a display panel by employing adjustable driving voltages such that redundant power waste can be suppressed.

### Description of the Prior Art

As known, an organic light-emitting diode (OLED) is a light-emitting diode having an emissive electroluminescent layer containing organic compounds.

Regarding display devices composed of OLEDs, such as computer displays, personal digital assistant (PDA) screens, television screens, and so on, OLED displays, unlike liquid crystal displays (LCDs), do not require a backlight to function and has many advantages of high brightness, easy manufacture, etc., for example.

Please refer to FIG. 1, which shows a schematic diagram of a conventional display driver architecture applied to an OLED display panel. The display driver 1 includes a display circuit 101 for receiving a plurality of display data Display_Data. In addition, a plurality of display input signals GMA_1 . . . GMA_K are electrically transmitted to the display circuit 101 for correspondingly generating a plurality of display output signals Output<P> . . . Output<0> for performing imaging on the display panel 2. A plurality of display pixel 202 are arranged in the display panel 2. For instance, the display pixels 202 may be configured in a pixel array for implementation. A power voltage ELVDD, which is a driving voltage, is given for operating and turning on the display pixel 202 of the display panel 2. FIG. 2 shows a relative diagram illustrating the conventional pixel array using the same power voltage ELVDD according to FIG. 1. As illustrated in FIG. 2, the plurality of display pixels 202 are configured in a pixel array, and each display pixel 202 is electrically connected with a data line DL, a sensing line SL, and is driven by the same power voltage ELVDD. As shown in the conventional scheme as FIG. 1 and FIG. 2 represent, it is obvious that in the prior art, each display pixel 202 of the display panel 2 uses the same power voltage ELVDD. The power voltage ELVDD for driving various display pixel 202 is not adjustable. Therefore, the power consumption of the display panel 2 may be enormously increased and become an issue to be overcome, which makes continual improvements in power efficiency remains desirable. To ensure that display panels, such as OLED displays, or micro-LED displays do not consume too much power, several methods have been discussed these days in the current technology and yet, challenges remain. Further reductions in power consumption and alternative methodologies in the field are still to be expected.

As a result, it, in view of all, should be apparent and obvious that there is indeed an urgent need for the professionals in the field for a novel and inventive display driver circuit to be developed, so as to solve the above-mentioned issues, and to enhance the power reduction efficiency.

### SUMMARY OF THE INVENTION

In order to overcome the above-mentioned disadvantages, one major objective in accordance with the present invention is to provide a novel display driver chip which is attached on a chip on film (COF) package, and the disclosed display driver chip can be provided for driving a plurality of pixels of a display panel. By employing the proposed display driver chip to drive a plurality of pixels of a display panel, it is believed that pixel-level power optimization is achieved. In other words, each pixel of the display panel is able to be driven by a selectable and adjustable driving voltage, ELVDD, according to its image brightness to be shown. As a result, it is believed that redundant power waste is avoided by the invention. In addition, the disclosed display driver chip and its driving method thereof can be applicable to an active display device composed of OLEDs or micro-LEDs, for example. However, the present invention is certainly not limited thereto. The display driver chip and driving method provided in the present invention may also be applied to other circuit configurations of various display devices. Many alternatives and modifications will be apparent to those skilled in the art, once informed by the present disclosure.

Among all, according to a sole embodiment of the invention, a display driver chip for driving a plurality of pixels of a display panel is provided. The provided display driver chip is attached on a chip on film (COF) package and the chip on film package includes a plurality of power lines and a plurality of data lines for driving the plurality of pixels. The disclosed display driver chip comprises a plurality of input power pads, a plurality of output power pads connected to the plurality of power lines of the chip on film package, a plurality of output data pads connected to the plurality of data lines of the chip on film package, and a power multiplexer which is electrically coupled to the plurality of input power pads. According to the present invention, the plurality of output power pads and the plurality of output data pads are located on the same side of the display driver chip. And the power multiplexer coupled to the plurality of input power pads is disposed to select one of a plurality of power voltages for outputting to one of the plurality of output power pads.

According to the embodiment of the present invention, the power multiplexer is operable to receive a power selecting signal such that the power multiplexer selects one of the plurality of power voltages according to the power selecting signal for outputting.

In one feasible embodiment, the power selecting signal can be provided by a power control circuit and the power control circuit receives a plurality of display data and determines the power selecting signal according to the plurality of display data.

Alternatively, in another feasible embodiment, then the power control circuit can either be electrically connected with a timing controller, and the timing controller is disposed to provide a power control signal. The power control signal can be computed or processed by the timing controller such that the timing controller generates and transmits the power control signal to the power control circuit, such that the power control circuit determines the power selecting signal according to the power control signal.

As a result, when a high brightness image is to be shown by the display panel, the power multiplexer selects a high power voltage from the plurality of power voltages for outputting. On the contrary, while a low brightness image, on the other hand, is to be shown by the display panel, then the power multiplexer selects a low power voltage from the plurality of power voltages for outputting. In view of the technical solutions of the present invention, it is believed that by employing the proposed display driver chip of the invention to drive the plurality of pixels of the display panel, a total power consumption compared to the prior arts is thus, greatly much reduced.

Moreover, according to a preferable embodiment of the present invention regarding the layout configurations of the display driver chip, it is feasible to dispose one of the plurality of output power pads between two of the plurality of output data pads.

Furthermore, in another aspect, the present invention may further provide to dispose a plurality of the power multiplexers in the display driver chip for driving the plurality of pixels of the display panel. Under such a circumstance, each of the plurality of the power multiplexers is coupled to the plurality of input power pads to receive the plurality of power voltages and each power multiplexer is adapted to select one of the plurality of power voltages for outputting. It is noted that, each of the plurality of the power multiplexers is correspondingly connected to one of the plurality of output power pads. In other words, when there are a plurality of power multiplexers disposed in the display driver chip, each power multiplexer receives its own power selecting signal such that each power multiplexer selects one of the plurality of power voltages according to the power selecting signal which is input to itself. It should be noted that, each of the plurality of power voltages which is selected by each power multiplexer can be identical or different. The present invention is certainly not limited thereto.

Therefore, to sum up, the disclosed display driver chip and driving method according to the invention can be applied to a display panel, which is an active display device composed of OLEDs or micro-LEDs, for instance. By adopting the proposed technical contents of the invention, the prior severe power consumption issues are believed to be eliminated in the present invention. Thereby, it is believed that the present invention achieves to successfully solves the problems of prior arts and performs as being highly competitive and able to be widely utilized in any related industries.

As a result, it has been proved and verified that the present invention is sophisticatedly designed, and the whole new driving techniques can be employed in a display driver circuit architecture and has succeeded in minimizing its IC power consumption. Meanwhile, redundant power waste is effectively avoided while compared to the prior arts.

These and other objectives of the present invention will become obvious to those of ordinary skill in the art after reading the following detailed description of preferred embodiments.

It is to be understood that both the foregoing general description and the following detailed description are exemplary and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 shows a schematic diagram of a conventional display driver architecture applied to an OLED display panel.

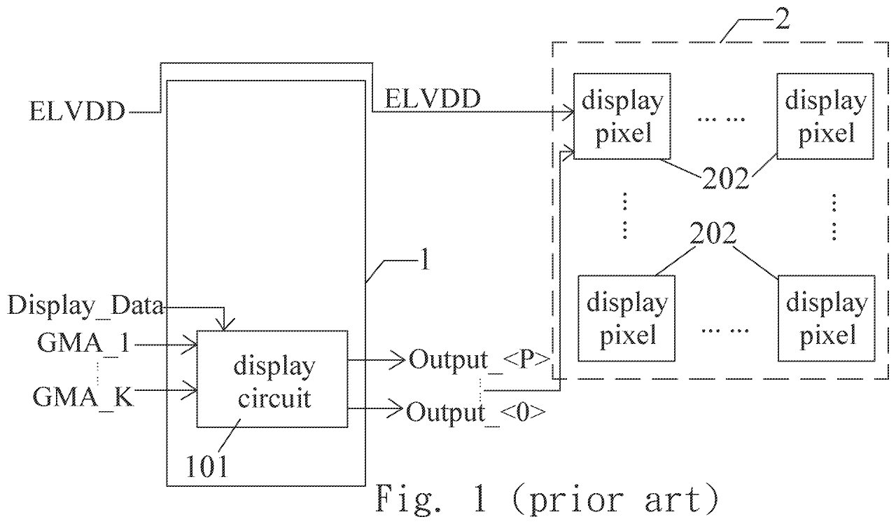

FIG. 2 shows a relative diagram illustrating the conventional pixel array using the same power voltage ELVDD according to FIG. 1.

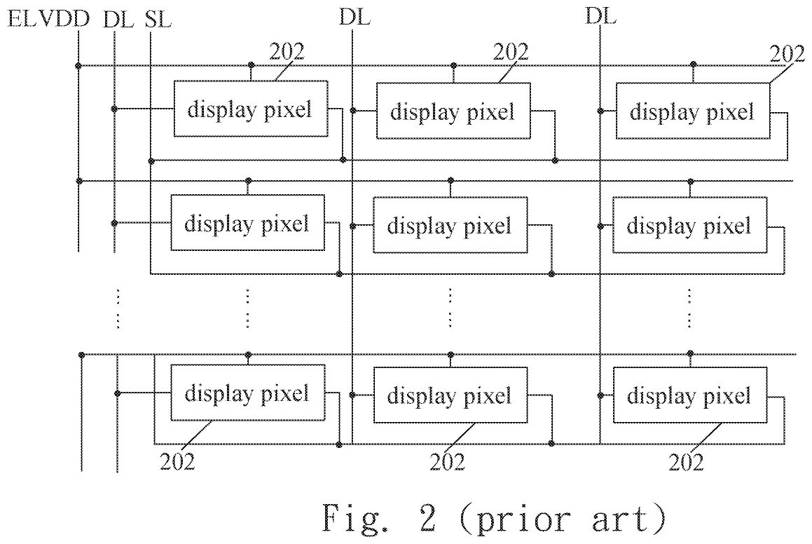

FIG. 3 schematically shows a structural diagram illustrating a display driver chip which is attached on a chip on film (COF) package in accordance with an embodiment of the present invention.

FIG. 4 schematically shows a structural diagram illustrating the disclosed display driver chip which is attached on the COF package in FIG. 3, is used for driving a plurality of pixels of a display panel.

FIG. 5 schematically shows a structural diagram illustrating a display driver chip in accordance with one embodiment of the present invention in which the power selecting signal is determined according to a plurality of display data.

FIG. 6 shows a flow chart illustrating a driving method of the display driver chip in view of the embodiment as shown in FIG. 5.

FIG. 7 shows a diagram schematically illustrating one of the plurality of pixels of the display panel according to one embodiment of the invention.

FIG. 8 schematically shows a structural diagram illustrating a display driver chip in accordance with an alternative embodiment of the present invention in which the power selecting signal is determined according to a power control signal.

FIG. 9 shows a flow chart illustrating a driving method of the display driver chip in view of the embodiment as shown in FIG. 8.

FIG. 10 schematically shows a structural diagram illustrating the disclosed display driver chip for driving a plurality of pixels of a display panel in accordance with another embodiment of the present invention, in which a plurality of power multiplexers are disposed.

FIG. 11 schematically shows a structural diagram illustrating the disclosed display driver chip for driving a plurality of pixels of a display panel in accordance with one another embodiment of the present invention, when a plurality of power multiplexers are disposed and a timing controller is further employed to provide a power control signal for determining a plurality of power selecting signals.

### DESCRIPTION OF THE PREFERRED EMBODIMENTS

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Unless otherwise specified, some conditional sentences or words, such as “can”, “could”, “might”, or “may”, usually attempt to express that the embodiment in the invention has, but it can also be interpreted as a feature, element, or step that may not be needed. In other embodiments, these features, elements, or steps may not be required.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Certain terms are used throughout the description and the claims to refer to particular components. One skilled in the art appreciates that a component may be referred to as different names. This disclosure does not intend to distinguish between components that differ in name but not in function. In the description and in the claims, the term “comprise” is used in an open-ended fashion, and thus should be interpreted to mean “include, but not limited to.” The phrases “be coupled to,” “couples to,” and “coupling to” are intended to compass any indirect or direct connection. Accordingly, if this disclosure mentioned that a first device is coupled with a second device, it means that the first device may be directly or indirectly connected to the second device through electrical connections, wireless communications, optical communications, or other signal connections with/without other intermediate devices or connection means.

The invention is particularly described with the following examples which are only for instance. Those skilled in the art will readily observe that numerous modifications and alterations of the device and method may be made while retaining the teachings of the invention. Accordingly, the following disclosure should be construed as limited only by the metes and bounds of the appended claims. In the whole patent application and the claims, except for clearly described content, the meaning of the article “a” and “the” includes the meaning of “one or at least one” of the element or component. Moreover, in the whole patent application and the claims, except that the plurality can be excluded obviously according to the context, the singular articles also contain the description for the plurality of elements or components. In the entire specification and claims, unless the contents clearly specify the meaning of some terms, the meaning of the article “wherein” includes the meaning of the articles “wherein” and “whereon”. The meanings of every term used in the present claims and specification refer to a usual meaning known to one skilled in the art unless the meaning is additionally annotated. Some terms used to describe the invention will be discussed to guide practitioners about the invention. Every example in the present specification cannot limit the claimed scope of the invention.

In the following descriptions, the Applicants of the invention provide a display driver chip which is attached on a chip on film (COF) package. The display driver chip attached on a COF package can be applied to drive a plurality of pixels of a display panel. According to the disclosed technical contents of the present invention, the display panel in which the proposed display driver chip is applied thereto, can be for instance, an active display device composed of OLEDs (organic light-emitting diode) or μLEDs (micro light-emitting-diode). However, it should be noted that the present invention is certainly not limited thereto. The disclosed technical contents of the present invention, regarding the proposed display driver chip structure scheme, as provided below may also be applied to other circuit configurations alternatively. For those skilled in the art, it is feasible to make adequate alternatives and/or modifications according to their practical circuit implementation requirements, and the present invention should still cover these alternatives and/or modifications in the claim scope with equality.

In the following, a display driver chip for driving a plurality of pixels of a display panel, wherein the display driver chip is attached on a COF package will be provided. By employing the present invention, it is believed that the proposed display driver chip and driving method thereof are able to achieve pixel-level power optimization for active display panel devices. And as a result, redundant power waste can be effectively avoided and suppressed.

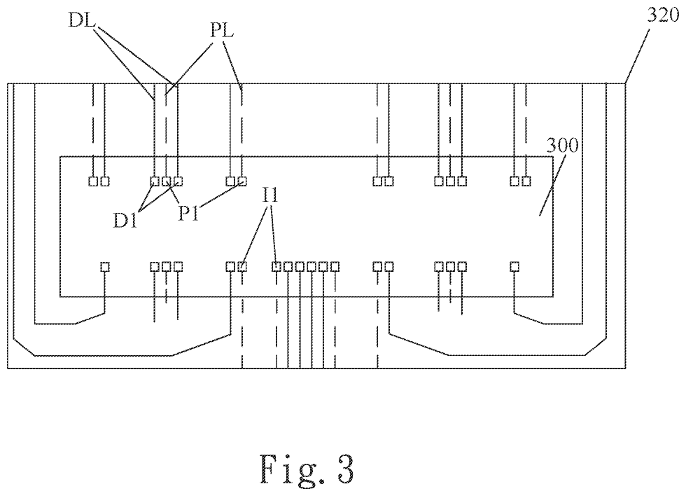

Please refer to FIG. 3, which schematically shows a structural diagram illustrating a display driver chip which is attached on a chip on film (COF) package in accordance with an embodiment of the present invention. As can be seen from FIG. 3, the disclosed display driver chip 300 is attached on a chip on film package 320. And the chip on film package 320 includes a plurality of power lines PL and a plurality of data lines DL. According to the embodiment of the present invention, the disclosed display driver chip 300 comprises a plurality of input power pads I1, a plurality of output power pads P1 and a plurality of output data pads D1. As illustrated in FIG. 3, it is shown that the plurality of output power pads P1 and the plurality of output data pads D1 are configured and located on the same side of the display driver chip 300.

Moreover, according to a preferred embodiment of the present invention, it is applicable that one of the plurality of output power pads P1, can be preferably disposed and located between two of the plurality of output data pads D1.

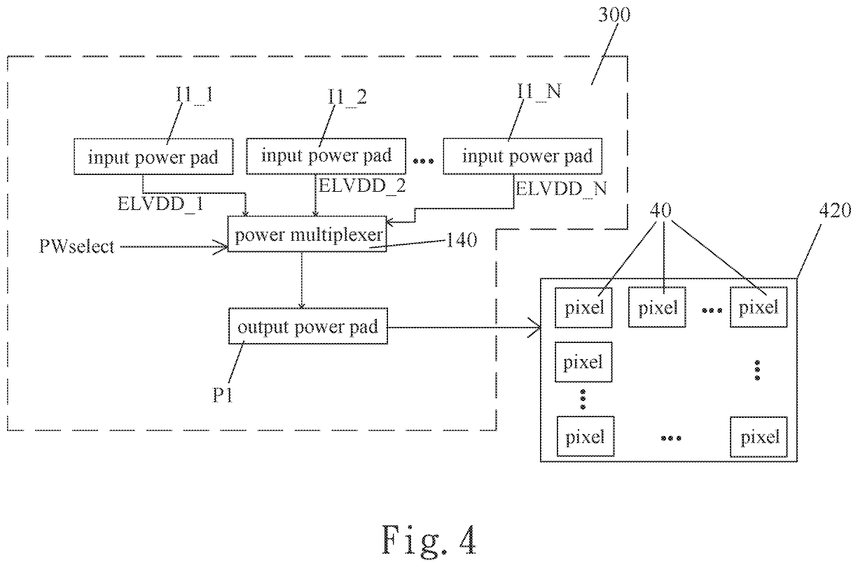

The plurality of power lines PL are electrically connected to the plurality of output power pads P1. In specific, each of the plurality of output power pads P1 is connected to each of the plurality of power lines PL. In addition, the plurality of data lines DL are electrically connected to the plurality of output data pads D1. In specific, each of the plurality of output data pads D1 is connected to each of the plurality of data lines DL. Please refer to FIG. 4 at the same time, in which FIG. 4 schematically shows a structural diagram illustrating the disclosed display driver chip which is attached on the COF package in FIG. 3, is used for driving a plurality of pixels of a display panel. As can be seen from FIG. 3 and FIG. 4, the disclosed display driver chip 300 is attached on the chip on film package 320, and the chip on film package 320 includes the plurality of power lines PL, which are electrically connected to the plurality of output power pads P1 of the display driver chip 300, and also includes the plurality of data lines DL, which are electrically connected to the plurality of output data pads D1 of the display driver chip 300 for driving the plurality of pixels 40 of the display panel 420. The display panel 420, in one embodiment, can be and yet not limited to an active display device composed of OLEDs or micro-LEDs.

In addition to the above-mentioned plurality of input power pads I1, the plurality of output power pads P1 and the plurality of output data pads D1, the display driver chip 300 as illustrated in FIG. 4, further comprises a power multiplexer 140 which is electrically coupled to the plurality of input power pads. In FIG. 4, for a better understanding to clarify the plurality of input power pads, this plurality of input power pads are illustrated each by I1_1, I1_2 . . . I1_N as indicated. And each of the plurality of input power pads I1_1, I1_2 . . . I1_N is configured so as to provide an input power voltage. For example, the input power pad I1_1 transmits and provides the power voltage ELVDD_1. The input power pad I1_2 transmits and provides the power voltage ELVDD_2. And the input power pad I1_N transmits and provides the power voltage ELVDD_N. According to the embodiment of the present invention, since the power multiplexer 140 is electrically coupled to the plurality of input power pads I1_1, I1_2 . . . I1_N, the power multiplexer 140 is able to receive the power voltages ELVDD_1, ELVDD_2 . . . ELVDD_N. And subsequently, the power voltages ELVDD_1, ELVDD_2 . . . ELVDD_N, also known as the driving voltage, can be given and selected by the power multiplexer 140, such that one of the plurality of power voltages ELVDD_1, ELVDD_2 . . . ELVDD_N can be chosen and selected by the power multiplexer 140 to output to an output power pad P1 for operating and turning on the pixels 40 of the display panel 420.

To be more specific, please also refer to FIG. 4, it is indicated that the power multiplexer 140 is operable to receive a power selecting signal PWselect such that the power multiplexer 140 selects one of the plurality of power voltages ELVDD_1, ELVDD_2 . . . ELVDD_N according to the power selecting signal PWselect for outputting to an output power pad P1. According to one embodiment of the present invention, the power multiplexer 140 may be a digitally coding multiplexer. For instance, when the power multiplexer 140 is a two-bit coded multiplexer, the power multiplexer 140 is operable to receive a plurality of power voltages ELVDD_1, ELVDD_2, ELVDD_3, ELVDD_4 (N=4) and select one power voltage out of these four power voltages ELVDD_1, ELVDD_2, ELVDD_3, ELVDD_4 for outputting. In another alternative embodiment while the power multiplexer 140 is a three-bit coded multiplexer, then the power multiplexer 140 will be operable to receive a plurality of power voltages ELVDD_1, ELVDD_2, ELVDD_3, ELVDD_4, ELVDD_5, ELVDD_6, ELVDD_7, ELVDD_8 (N=8) and select one power voltage out of these eight power voltages ELVDD_1, ELVDD_2, ELVDD_3, ELVDD_4, ELVDD_5, ELVDD_6, ELVDD_7, ELVDD_8 for outputting.

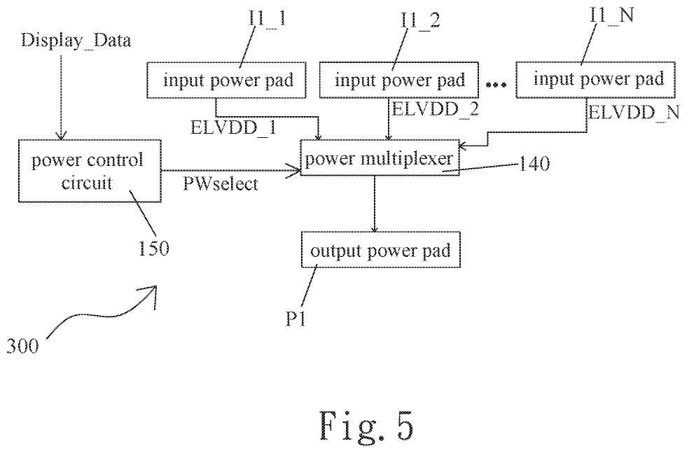

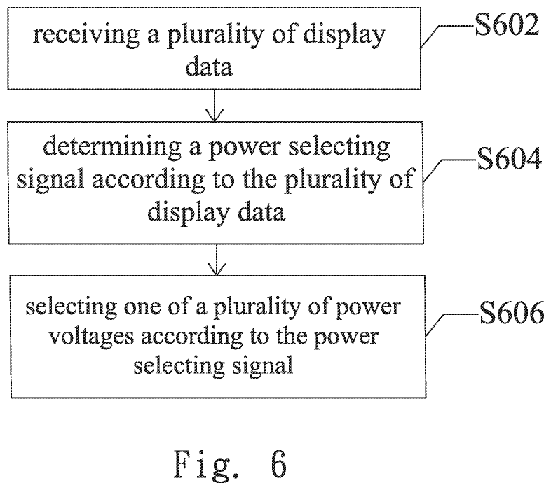

FIG. 5 schematically shows a structural diagram illustrating a display driver chip in accordance with one embodiment of the present invention in which the power selecting signal is determined according to a plurality of display data. FIG. 6 shows a flow chart illustrating a driving method of the display driver chip in view of the embodiment as shown in FIG. 5. As referring to the embodiment in FIG. 5, the proposed display driver chip 300 may further comprise a power control circuit 150, which is electrically connected to the power multiplexer 140. The power control circuit 150 is operable to receive a plurality of display data Display_Data such that the power control circuit 150 is adapted to determine the power selecting signal PWselect upon receiving the plurality of display data Display_Data. FIG. 6 shows the corresponding operation flow chart. As illustrated in the step S602 in FIG. 6, the power control circuit 150 receives the plurality of display data Display_Data. Subsequently, after the power control circuit 150 receives the plurality of display data Display_Data, the power control circuit 150 is able to determine the power selecting signal PWselect according to the plurality of display data Display_Data, as illustrated in the step S604 in FIG. 4. The power multiplexer 140 is electrically connected to the power control circuit 150 to receive the power selecting signal PWselect such that in the step S606, the power multiplexer 140 selects one of the plurality of power voltages ELVDD_1, ELVDD_2 . . . ELVDD_N for outputting to one of the plurality of output power pads P1.

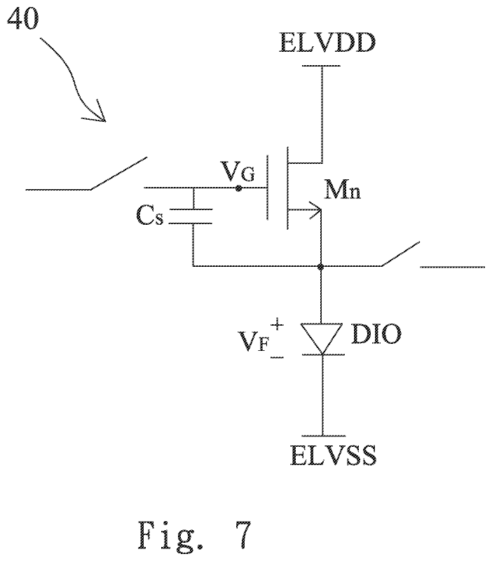

FIG. 7 schematically shows a diagram illustrating one of the plurality of pixels of the display panel according to an embodiment of the present invention. As indicated, components of the pixel 40 may include a transistor Mn, a capacitor Cs and a diode DIO, for instance. A drain of the transistor Mn is electrically connected with the driving power voltage ELVDD, and a gate of the transistor Mn is supplied with a gate voltage V_{G}. A source of the transistor Mn is electrically connected with the diode DIO, and the diode DIO has a forward voltage V_{F}. A cathode of the diode DIO is electrically connected with a source voltage ELVSS. The transistor Mn has a threshold voltage V_{TH}. The capacitor Cs is connected between the gate and the source of the transistor Mn for storing display data. To ensure that the transistor Mn works in a saturation region, a minimum value (ELVDDₘᵢₙ) of its driving power voltage ELVDD can be determined as follows.

ELVDDₘᵢₙ=V_{G}−V_{TH}+V_{F}+ELVSS

And therefore, as referring to the structural diagram in FIG. 5 as well as its driving method as described in FIG. 6, when the plurality of display data Display_Data is used for showing a low brightness image, for example, a low gray-scale image, then it is believed that the power multiplexer 140 is able to select a low power voltage from the plurality of power voltages ELVDD_1, ELVDD_2 . . . ELVDD_N for outputting. On the other hand, if the plurality of display data Display_Data is used for showing a high brightness image, for example, a high gray-scale image, then the power multiplexer 140, instead selects a high power voltage from the plurality of power voltages ELVDD_1, ELVDD_2 . . . ELVDD_N for outputting. As a result, by employing the selectable and adjustable power voltages ELVDD_1, ELVDD_2 . . . ELVDD_N, the plurality of pixels 40 of the display panel 420 can be driven by a selectable power voltage according to its actual output brightness and/or gray-scale as required. And since the driving power voltage can be alternatively reduced as required, a total IC power consumption of the display driver chip is believed to be decreased as well, indicating that, redundant power waste can be effectively avoided. As a result, it is thus, believed that the disclosed display driver chip for driving the plurality of pixels of the display panel are effective in solving the severe power-consuming problems existing in the prior arts.

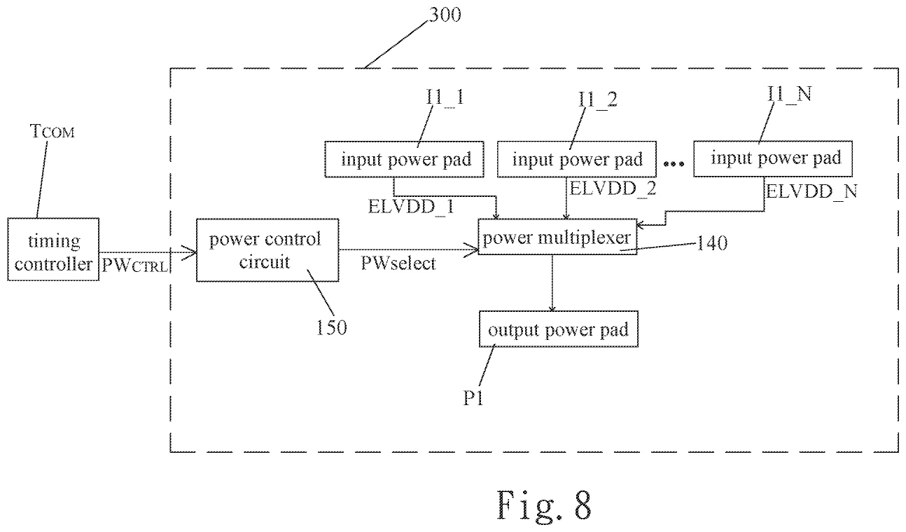

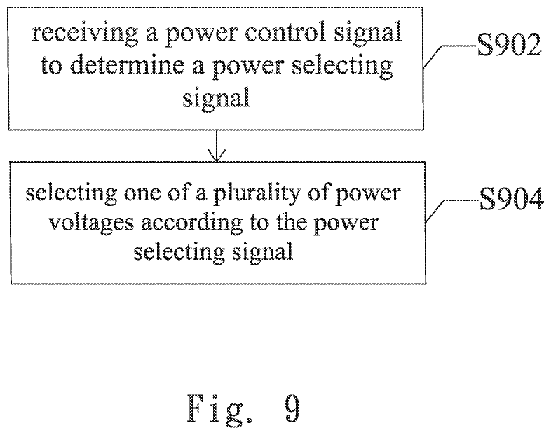

Also, in another aspect, please refer to FIG. 8 for another alternative embodiment of the invention. FIG. 8 schematically shows a structural diagram illustrating a display driver chip in accordance with the alternative embodiment of the present invention, in which the power selecting signal is determined according to a power control signal. FIG. 9 shows a flow chart illustrating a driving method of the display driver chip in view of the embodiment as shown in FIG. 8. As referring to the embodiment in FIG. 8, the proposed display driver chip 300 may further comprise a power control circuit 150, which is electrically connected to the power multiplexer 140. In such an alternative embodiment, the power control circuit 150 is operable to receive a power control signal PW_{CTRL} such that the power control circuit 150 is adapted to determine the power selecting signal PWselect according to the power control signal PW_{CTRL}. Please refer to FIG. 9 for the corresponding operation flow chart.

In such an alternative embodiment, the power control circuit 150 is electrically connected with a timing controller T_{COM}, and the power control signal PW_{CTRL} is provided from the timing controller T_{COM} for determining the power selecting signal PWselect. In addition, the power control circuit 150 of the display driver chip 300 may be coupled to the timing controller T_{COM} also for signal synchronization, such that a plurality of display data can be further transmitted to one display circuit of the display driver chip 300 for imaging. As such, when receiving the plurality of display data, the display circuit of the display driver chip 300 can be operable to generate a plurality of display output signals in response to a plurality of display input signals in order to drive the pixels of the display panel and showing images on the display panel. Since the technical contents for showing images are acknowledged, the present invention omits superfluous descriptions.

Specifically, in view of the embodiment as illustrated in FIG. 8, what differs from the previous embodiment as shown in FIG. 5 is that, the power control circuit 150 determines the power selecting signal PWselect according to the power control signal PW_{CTRL} which is provided from the timing controller T_{COM}. Please refer to FIG. 9 for the driving method of the display driver chip regarding the embodiment as shown in FIG. 8.

According to the alternative embodiment of the present invention in FIG. 8, the power control circuit 150 receives a power control signal PW_{CTRL} from the timing controller T_{COM} to determine the power selecting signal PWselect (as illustrated in the step S902 in FIG. 9). In one embodiment, the power control signal PW_{CTRL} can be computed and processed by the timing controller T_{COM} and the generated power control signal PW_{CTRL} will be transmitted to the power control circuit 150. Subsequently, after the power control circuit 150 receives the power control signal PW_{CTRL}, the power control circuit 150 is able to determine the power selecting signal PWselect according to the power control signal PW_{CTRL}, as illustrated in the step S902 in FIG. 9.

And then, since the power multiplexer 140 is electrically coupled to the power control circuit 150 to receive the power selecting signal PWselect, it is derived that in the step S904, the power multiplexer 140 is able to select one of a plurality of power voltages ELVDD_1, ELVDD_2 . . . ELVDD_N according to the power selecting signal PWselect for outputting to one of the plurality of output power pads P1.

The architecture of the pixel 40 in the previously described embodiment in FIG. 7 may be similarly applied to the architecture in FIG. 8 or the other embodiments. Therefore, as previously described, a minimum value (ELVDDₘᵢₙ) of a driving power voltage ELVDD of the pixel 40 can be determined as follows.

ELVDDₘᵢₙ=V_{G}−V_{TH}+V_{F}+ELVSS

As a result, it is believed that when the pixel of the display panel, is used for showing a low brightness image, for example, a low gray-scale image, then the power multiplexer 140 selects a low power voltage from the plurality of power voltages ELVDD_1, ELVDD_2 . . . ELVDD_N for outputting. On the other hand, if the pixel of the display panel is used for showing a high brightness image, for example, a high gray-scale image, then the power multiplexer 140, instead selects a high power voltage from the plurality of power voltages ELVDD_1, ELVDD_2 . . . ELVDD_N for outputting. By employing the selectable and adjustable power voltages ELVDD_1, ELVDD_2 . . . ELVDD_N, the pixel of the display panel can be driven by a selectable and adjustable power voltage according to its actual output brightness and/or gray-scale as required. Therefore, pixel-level power optimization for display panel devices is successfully achieved.

According to the present invention, the foregoing disclosed display driver chip for driving a plurality of pixels of a display panel as well as its driving method thereof are proposed to be applied to a display panel, which is an active display device composed of OLEDs or micro-LEDs, for example. And yet the invention is not limited to such light-emitting diodes. Alternative preferable components may also be compatible.

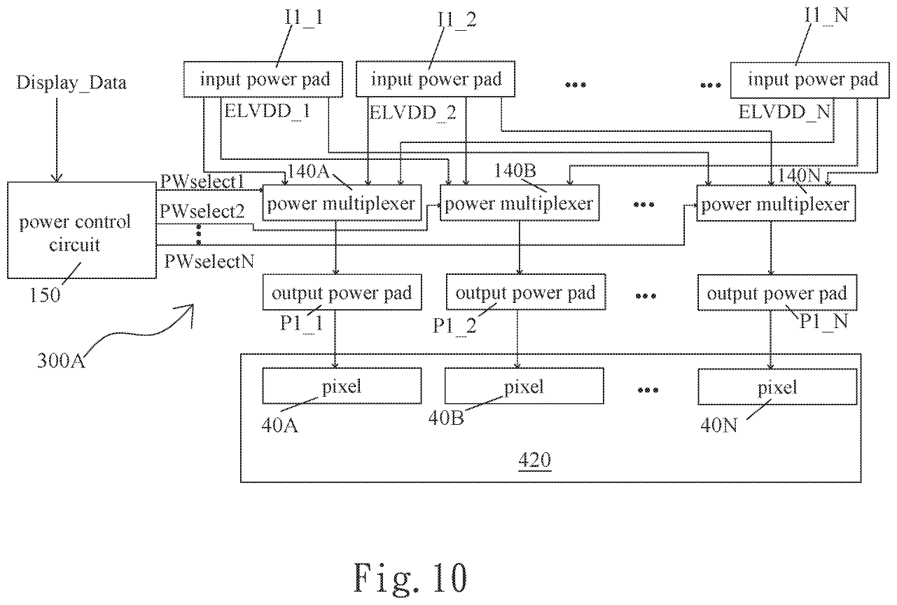

And furthermore, please proceed to refer to FIG. 10 for one variant modification of the invention. FIG. 10 schematically shows a structural diagram illustrating the disclosed display driver chip for driving a plurality of pixels of a display panel in accordance with another embodiment of the present invention, in which a plurality of power multiplexers are disposed.

As can be seen from FIG. 10, according to such an embodiment, in addition to the plurality of input power pads I1_1, I1_2 . . . I1_N, the display driver chip 300A may further include a plurality of power multiplexers. Since one power multiplexer is correspondingly disposed in relative to one output power pad, a plurality of output power pads each illustrated as P1_1, P1_2 . . . P1_N are shown and coupled to the plurality of power multiplexers. In FIG. 10, for a better understanding to clarify the plurality of power multiplexers, this plurality of power multiplexers are illustrated each by 140A, 140B . . . 140N as indicated.

According to the embodiment, each of the plurality of the power multiplexers 140A, 140B . . . 140N is electrically coupled to the plurality of input power pads I1_1, I1_2 . . . I1_N to receive the power voltages ELVDD_1, ELVDD_2 . . . ELVDD_N. And each of the plurality of the power multiplexers 140A, 140B . . . 140N receives a power selecting signal from the power control circuit 150. For instance, the power multiplexer 140A receives a power selecting signal PWselect1 from the power control circuit 150. The power multiplexer 140B receives a power selecting signal PWselect2 from the power control circuit 150 and the power multiplexer 140N receives a power selecting signal PWselectN from the power control circuit 150. In such an embodiment, the power control circuit 150 is adapted to receive a plurality of display data Display_data and determines each of the power selecting signals PWselect1, PWselect2 . . . PWselectN according to the plurality of display data Display_data.

As a result, after receiving the power selecting signal which is input to the power multiplexer, one power multiplexer is able to select one of the plurality of power voltages ELVDD_1, ELVDD_2 . . . ELVDD_N for outputting to one output power pad in order to drive one pixel of the display panel.

For instance, as shown in FIG. 10, the power multiplexer 140A is adapted to being coupled to the plurality of input power pads I1_1, I1_2 . . . I1_N to receive the power voltages ELVDD_1, ELVDD_2 . . . ELVDD_N. And after the power multiplexer 140A receives the power selecting signal PWselect1 which is input to it, the power multiplexer 140A is able to select one power voltage out of the power voltages ELVDD_1, ELVDD_2 . . . ELVDD_N according to the power selecting signal PWselect1. As a result, the selected power voltage can be output and transmitted to the output power pad P1_1 which is coupled with the power multiplexer 140A, so as to drive a pixel 40A of the display panel 420.

As for the power multiplexer 140B, the power multiplexer 140B is also adapted to being coupled to the plurality of input power pads I1_1, I1_2 . . . I1_N to receive the power voltages ELVDD_1, ELVDD_2 . . . ELVDD_N. And after the power multiplexer 140B receives the power selecting signal PWselect2 which is input to it, the power multiplexer 140B is able to select one power voltage out of the power voltages ELVDD_1, ELVDD_2 . . . ELVDD_N according to the power selecting signal PWselect2. And, the selected power voltage is output and transmitted to the output power pad P1_2 which is coupled with the power multiplexer 140B, so as to drive a pixel 40B of the display panel 420.

Regarding the power multiplexer 140N, in the similar manners, the power multiplexer 140N is adapted to being coupled to the plurality of input power pads I1_1, I1_2 . . . I1_N to receive the power voltages ELVDD_1, ELVDD_2 . . . ELVDD_N. And after the power multiplexer 140N receives the power selecting signal PWselectN which is input to it, the power multiplexer 140N will be able to select one power voltage out of the power voltages ELVDD_1, ELVDD_2 . . . ELVDD_N according to the power selecting signal PWselectN. And as a result, the selected power voltage can be output and transmitted to the output power pad P1_N which is coupled with the power multiplexer 140N, so as to drive a pixel 40N of the display panel 420.

According to such an embodiment of the invention when a plurality of power multiplexers 140A, 140B . . . 140N are configured in the display driver chip, it should be understood that each of the plurality of power voltages ELVDD_1, ELVDD_2 . . . ELVDD_N which is selected by each power multiplexer 140A, 140B . . . 140N can be identical or different. The power voltage to be selected and output by each power multiplexer 140A, 140B . . . 140N can be determined according to its individual power selecting signal PWselect1, PWselect2 . . . PWselectN, which are related to the display data Display_data for example, to show a high or a low brightness image.

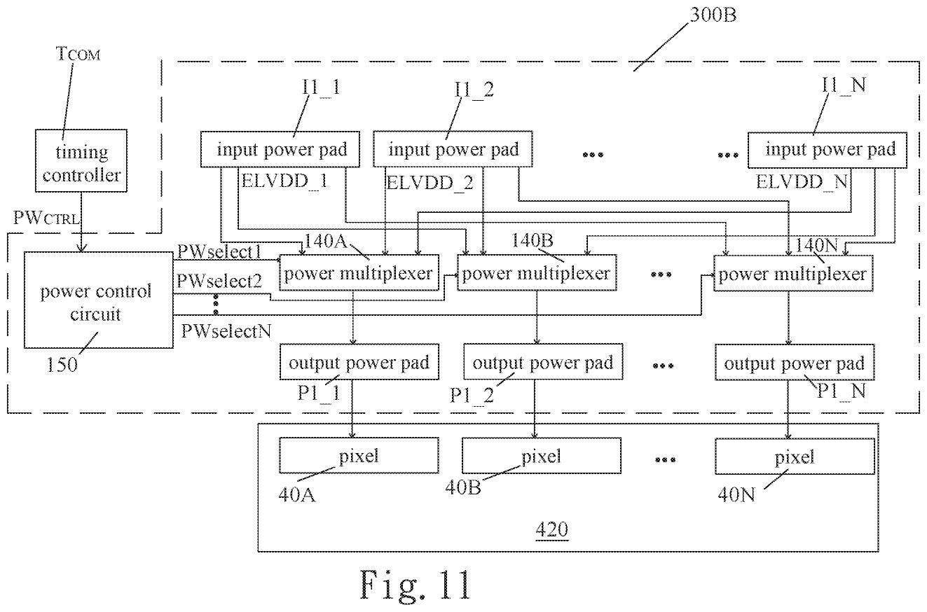

And also in another aspect, please proceed to refer to FIG. 11 for the other variant modification of the invention. FIG. 11 schematically shows a structural diagram illustrating the disclosed display driver chip for driving a plurality of pixels of a display panel in accordance with one another embodiment of the present invention, when a plurality of power multiplexers are disposed and a timing controller is further employed to provide a power control signal.

As can be seen from FIG. 11, the disclosed display driver chip 300B in this embodiment is further electrically connected to a timing controller T_{COM} so that the power control circuit 150 of the display driver chip 300B receives a power control signal PW_{CTRL} from the timing controller T_{COM} to determine the power selecting signals PWselect1, PWselect2 . . . PWselectN. In general, the power control signal PW_{CTRL} can be either computed or processed by the timing controller T_{COM} such that the generated power control signal PW_{CTRL} can be transmitted to the power control circuit 150. Subsequently, after the power control circuit 150 receives the power control signal PW_{CTRL}, the power control circuit 150 is able to determine the power selecting signals PWselect1, PWselect2 . . . PWselectN according to the power control signal PW_{CTRL}.

And therefore, after receiving the power selecting signals PWselect1, PWselect2 . . . PWselectN which is individually input to the power multiplexers 140A, 140B . . . 140N, each of the power multiplexers 140A, 140B . . . 140N will be able to select one power voltage out of the plurality of power voltages ELVDD_1, ELVDD_2 . . . ELVDD_N for outputting to one output power pad P1_1, P1_2 . . . P1_N in order to drive each pixel 40A, 40B . . . 40N of the display panel 420. Each of the plurality of power voltages ELVDD_1, ELVDD_2 . . . ELVDD_N to be selected by each power multiplexer 140A, 140B . . . 140N can be identical or different. Overall, according to the technical solution of the present invention, the power voltage to be selected and output by each power multiplexer 140A, 140B . . . 140N can be determined according to its individual power selecting signal PWselect1, PWselect2 . . . PWselectN, which are related to the power control signal PW_{CTRL} for example, for the pixel 40A, 40B . . . 40N to perform imaging a high or a low brightness frame.

As a result, it is believed that the Applicants of the invention have proposed a plurality of practical embodiments as illustrated in the earlier paragraphs to verify the objectives of the present invention. And based on at least one embodiment provided above, it is believed that the proposed display driver chip and driving method of the present invention are characterized by an adjustable and selectable driving power voltage ELVDD of each pixel unit on the display panel. By employing the disclosed power multiplexer, it is believed that various pixel unit for showing different brightness of images can be driven by an adequate driving power voltage ELVDD as required, so as to avoid power waste. And by employing the proposed display driver chip for driving a plurality of pixels of a display panel, it ensures that pixel-level power optimization can be effectively achieved. In addition, the present invention is believed as beneficial to reducing IC power consumption. As a result, when compared to the prior arts, it is obvious that the present invention apparently shows much more effective performances than before. In addition, it is believed that the present invention is instinct, effective and highly competitive for IC technology and industries in the market nowadays, whereby having extraordinary availability and competitiveness for future industrial developments and being in condition for early allowance.

It will be apparent to those skilled in the art that various modifications and variations can be made to the present invention without departing from the scope or spirit of the invention. In view of the foregoing, it is intended that the present invention cover modifications and variations of this invention provided they fall within the scope of the invention and its equivalent.

What is claimed is:

1. A display driver chip for driving a plurality of pixels of a display panel, wherein the display driver chip is attached on a chip on film (COF) package and the chip on film package includes a plurality of power lines and a plurality of data lines for driving the plurality of pixels, the display driver chip comprising:
a plurality of input power pads;
a plurality of output power pads connected to the plurality of power lines of the chip on film package;
a plurality of output data pads connected to the plurality of data lines of the chip on film package, wherein the plurality of output power pads and the plurality of output data pads are located on the same side of the display driver chip; and
a power multiplexer coupled to the plurality of input power pads to select one of a plurality of power voltages for outputting to one of the plurality of output power pads.

2. The display driver chip for driving the plurality of pixels of the display panel according to claim 1, wherein one of the plurality of output power pads is located between two of the plurality of output data pads.

3. The display driver chip for driving the plurality of pixels of the display panel according to claim 1, wherein the power multiplexer is operable to receive a power selecting signal such that the power multiplexer selects one of the plurality of power voltages according to the power selecting signal for outputting.

4. The display driver chip for driving the plurality of pixels of the display panel according to claim 3, wherein the power selecting signal is provided by a power control circuit and the power control circuit receives a plurality of display data and determines the power selecting signal according to the plurality of display data.

5. The display driver chip for driving the plurality of pixels of the display panel according to claim 4, wherein when the plurality of display data is used for showing a high brightness image, the power multiplexer selects a high power voltage from the plurality of power voltages for outputting, and when the plurality of display data is used for showing a low brightness image, the power multiplexer selects a low power voltage from the plurality of power voltages for outputting.

6. The display driver chip for driving the plurality of pixels of the display panel according to claim 3, wherein the power selecting signal is provided by a power control circuit and the power control circuit receives a power control signal and determines the power selecting signal according to the power control signal.

7. The display driver chip for driving the plurality of pixels of the display panel according to claim 6, wherein the power control circuit is electrically connected with a timing controller, and the power control signal is provided from the timing controller for determining the power selecting signal.

8. The display driver chip for driving the plurality of pixels of the display panel according to claim 7, wherein when the plurality of pixels of the display panel are used for showing a high brightness image, the power multiplexer selects a high power voltage from the plurality of power voltages for outputting, and when the plurality of pixels of the display panel are used for showing a low brightness image, the power multiplexer selects a low power voltage from the plurality of power voltages for outputting.

9. The display driver chip for driving the plurality of pixels of the display panel according to claim 1, wherein the display panel is an active display device composed of OLEDs or micro-LEDs.

10. The display driver chip for driving the plurality of pixels of the display panel according to claim 1, further comprising a plurality of the power multiplexers, wherein each of the plurality of the power multiplexers is coupled to the plurality of input power pads to select one of the plurality of power voltages for outputting, and each of the plurality of the power multiplexers is correspondingly connected to one of the plurality of output power pads.

11. The display driver chip for driving the plurality of pixels of the display panel according to claim 10, wherein each of the plurality of the power multiplexers receives a power selecting signal such that each of the plurality of the power multiplexers selects one of the plurality of power voltages according to the power selecting signal which is input to each of the plurality of the power multiplexers.

12. The display driver chip for driving the plurality of pixels of the display panel according to claim 11, wherein one of the plurality of power voltages which is selected by each of the plurality of the power multiplexers is identical or different.

13. The display driver chip for driving the plurality of pixels of the display panel according to claim 1, further comprising a display circuit, wherein a plurality of display data is transmitted to the display circuit for driving the plurality of pixels of the display panel to perform imaging.
